(19) United States
(12) Patent Application Publication
(10) Pub. No.: US 2026/0076010 A1
(43) Pub. Date: Mar. 12, 2026

(54) LENS, LENS STRUCTURE, AND LIGHT-EMITTING MODULE

(71) Applicant: Nichia Corporation, Anan-shi (JP)

(72) Inventor: Morihito YAMAMOTO, Tokushima-shi (JP)

(73) Assignee: Nichia Corporation, Anan-shi (JP)

(21) Appl. No.: 19/317,311

(22) Filed: Sep. 3, 2025

(30) Foreign Application Priority Data
Sep. 9, 2024 (JP) 2024-155196

(51) Int. Cl. H10H 29/855; H10H 29/24; H10H 29/856

(52) U.S. Cl. CPC H10H 29/855; H10H 29/24; H10H 29/856

(57) ABSTRACT

A lens includes: a first lens portion having a positive refractive power; and a second lens portion having a positive refractive power and located outward of an outer edge of the first lens portion in a top view. The first lens portion has an optical axis, a first light incident surface, and a first light exit surface located opposite to the first light incident surface. The second lens portion has a second light incident surface and a second light exit surface located opposite to the second light incident surface. In a cross section including the optical axis of the first lens portion: a lens main axis of the second lens portion is inclined with respect to the optical axis of the first lens portion such that the lens main axis has an increasing distance from the optical axis toward the second light exit surface from the second light incident surface.

### CROSS-REFERENCE TO RELATED APPLICATION

This application claims priority to Japanese Patent Application No. 2024-155196, filed on Sep. 9, 2024, the disclosure of which is hereby incorporated by reference in its entirety.

### TECHNICAL FIELD

The present disclosure relates to a lens, a lens structure, and a light-emitting module.

### BACKGROUND

Light-emitting modules including semiconductor elements such as light-emitting diodes (LEDs) have been widely used. As a lens used in such a light-emitting module, for example, Japanese Patent Publication No. 2016-509360 discloses a lens that includes a central lens portion and an annular lens portion and is disposed in front of at least one solid-state light source in a light emission direction. In the lens, the central lens portion has a dome-shaped outer surface and the annular lens portion has an outer surface with a convex shape.

### SUMMARY

An object of certain embodiments of the present disclosure is to provide a lens, a lens structure, and a light-emitting module that reduce stray light.

A lens according to an embodiment of the present disclosure includes: a first lens portion having a positive refractive power; and a second lens portion having a positive refractive power and located outward of an outer edge of the first lens portion in a top view, wherein the first lens portion has an optical axis and has a first light incident surface and a first light exit surface located opposite to the first light incident surface, the second lens portion has a second light incident surface and a second light exit surface located opposite to the second light incident surface, and in one cross section including the optical axis, the second lens portion has a lens main axis, and the lens main axis is inclined with respect to the optical axis in a manner that the lens main axis has an increasing distance from the optical axis toward the second light exit surface from the second light incident surface.

A lens structure according to an embodiment of the present disclosure includes: the lens; and a light-transmissive member including a third lens portion disposed above the first lens portion and the second lens portion, and a support portion supporting the third lens portion.

A light-emitting module according to an embodiment of the present disclosure includes: the lens; and a light source disposed facing a first surface of the lens, the first surface including the first light incident surface and the second light incident surface.

A light-emitting module according to an embodiment of the present disclosure includes: a lens including a first lens portion having a positive refractive power, and a second lens portion having a positive refractive power and located outward of an outer edge of the first lens portion in a top view, and a light source, wherein the first lens portion has an optical axis and has a first light incident surface and a first light exit surface located opposite to the first light incident surface, the second lens portion has a second light incident surface and a second light exit surface located opposite to the second light incident surface, the light source is disposed facing a first surface of the lens, the first surface including the first light incident surface and the second light incident surface, the second lens portion is provided in contact with an outer edge of the first lens portion, and in one cross section including the optical axis, a boundary light beam emitted from a light-emitting point of the light source located immediately below a boundary between the first lens portion and the second lens portion, in a direction along the optical axis, is emitted from the second light exit surface at an angle in a range from 30 degrees to 50 degrees with respect to the optical axis in a manner that the boundary light beam has an increasing distance from the optical axis, and passes through a peak point where illuminance of irradiation light from the light-emitting point is maximized on an irradiation plane being orthogonal to the optical axis and located above the lens.

With an embodiment of the present disclosure, a lens, a lens structure, and a light-emitting module that reduce stray light can be provided.

### BRIEF DESCRIPTION OF DRAWINGS

FIG. 1 is a schematic top view of a light-emitting module including a lens according to a first embodiment.

FIG. 2 is a schematic cross-sectional view taken along line II-II in FIG. 1.

FIG. 3 is a schematic cross-sectional view illustrating a behavior of light emitted from the light-emitting module including the lens according to the first embodiment.

FIG. 4 is a schematic top view illustrating a configuration of a light source of the light-emitting module including the lens according to the first embodiment.

FIG. 5 is a schematic cross-sectional view taken along line V-V in FIG. 4.

FIG. 6 is a schematic view illustrating the likelihood of generation of stray light at each position of a light-emitting unit in the light-emitting module including the lens according to the first embodiment.

FIG. 7A is a diagram showing an illuminance distribution in a case in which only one light-emitting unit that is likely to generate stray light is caused to emit light, in the light-emitting module including the lens according to the first embodiment.

FIG. 7B is a diagram showing an illuminance distribution in a case in which only one light-emitting unit that is likely to generate stray light is caused to emit light, in a light-emitting module including a lens according to Reference Example 1.

FIG. 8 is a schematic cross-sectional view illustrating inclination angles of a second light incident surface and a second light exit surface at a boundary between a first lens portion and a second lens portion of the lens according to the first embodiment.

FIG. 9 is a diagram showing a relationship between an illuminance distribution in a case in which only one light-emitting unit that is likely to generate stray light is caused to emit light, in the light-emitting module according to the first embodiment, and the inclination of the second light incident surface and the second light exit surface in FIG. 8.

FIG. 10 is a schematic top view of a light-emitting module including a lens structure according to a second embodiment.

FIG. 11 is a schematic cross-sectional view taken along line XI-XI in FIG. 10.

FIG. 12 is a schematic cross-sectional view illustrating a behavior of light emitted from the light-emitting module including the lens structure according to the second embodiment.

FIG. 13A is a diagram showing an illuminance distribution in a case in which only one light-emitting unit that is likely to generate stray light is caused to emit light, in the light-emitting module including the lens structure according to the second embodiment.

FIG. 13B is a diagram showing an illuminance distribution in a case in which only one light-emitting unit that is likely to generate stray light is caused to emit light, in a light-emitting module including a lens structure according to Reference Example 2.

FIG. 14 is a schematic top view of a light-emitting module including a lens structure according to a third embodiment.

FIG. 15 is a schematic cross-sectional view taken along line XV-XV in FIG. 14.

FIG. 16 is a schematic cross-sectional view illustrating a behavior of light emitted from the light-emitting module including the lens structure according to the third embodiment.

FIG. 17A is a diagram showing an illuminance distribution in a case in which only one light-emitting unit that is likely to generate stray light is caused to emit light, in the light-emitting module including the lens structure according to the third embodiment.

FIG. 17B is a diagram showing an illuminance distribution in a case in which only one light-emitting unit that is likely to generate stray light is caused to emit light, in a light-emitting module including a lens structure according to Reference Example 3.

FIG. 18 is a schematic top view of a light-emitting module including a lens structure according to a modification of the third embodiment.

### DETAILED DESCRIPTION

Lenses, lens structures, and light-emitting modules according to embodiments of the present disclosure will be described in detail with reference to the drawings. The following embodiments are examples of lenses, lens structures, and light-emitting modules to embody the technical concept of the present embodiment, and the present embodiment is not limited to the embodiments described below. The dimensions, materials, shapes, relative arrangements, and the like of components described in the embodiments are not intended to limit the scope of the present disclosure, but are merely illustrative examples, unless otherwise specifically stated. Note that the sizes, positional relationship, or the like of members illustrated in the drawings may be exaggerated for clarity of description. In the following description, members having the same terms and reference characters represent the same or similar members, and a detailed description of these members is omitted as appropriate. As a cross-sectional view, an end view illustrating only a cut surface may be used.

In the following drawings, directions may be indicated by an X axis, a Y axis, and a Z axis corresponding to directions orthogonal to each other. A first direction X along the X axis and a second direction Y along the Y axis indicate directions along a light-emitting surface of a light-emitting unit of a light-emitting module according to an embodiment. A Z direction along the Z-axis indicates a direction orthogonal to the light-emitting surface. In other words, the light-emitting surface of the light-emitting unit is parallel to an XY plane, and the Z-axis is orthogonal to the XY plane.

Further, the direction in the first direction X to which the arrow points is the +X side and the opposite side to the +X side is the −X side, the direction in the second direction Y to which the arrow points is the +Y side and the opposite side to the +Y side is the −Y side. The direction the arrow points to in the Z direction is the +Z side, and the opposite side to the +Z side is the −Z side. In the embodiments, the light-emitting unit included in the light-emitting module emits light toward the +Z side as an example. Note that this does not limit the orientation of the lens, the lens structure, and the light-emitting module during use, and the lens, the lens structure, and the light-emitting module may be in any orientation.

In the present specification, a surface of an object when viewed from the +Z side is referred to as an “upper surface,” and a surface of the target object when viewed from the −Z side is referred to as a “lower surface.” In addition, the +Z side when viewed from the object may be referred to as an “upper side” and the −Z side when viewed from the object may be referred to as a “lower side.” In the following embodiments, being “aligned with the X-axis, the Y-axis, or the Z-axis” includes the case in which an object has an inclination within a range of +10° relative to the corresponding axis. In the present embodiment, the orthogonality may include an error within +10° with respect to 90°. In the present specification, “along” may include an error within +10° with respect to 0°. Furthermore, “disposing” includes not only a case of disposing two objects in direct contact with each other but also includes a case of indirectly disposing, for example, disposing one object and the other object with another member provided therebetween.

In the present specification or the claims, when a plurality of constituent components are provided and these constituent components are to be denoted individually, the constituent components may be distinguished by adding terms such as “first,” “second,” and the like in front of the terms of the constituent components. Objects to be distinguished may differ between the present specification and the claims.

### First Embodiment

### Configuration of Light-Emitting Module Including Lens According to First Embodiment

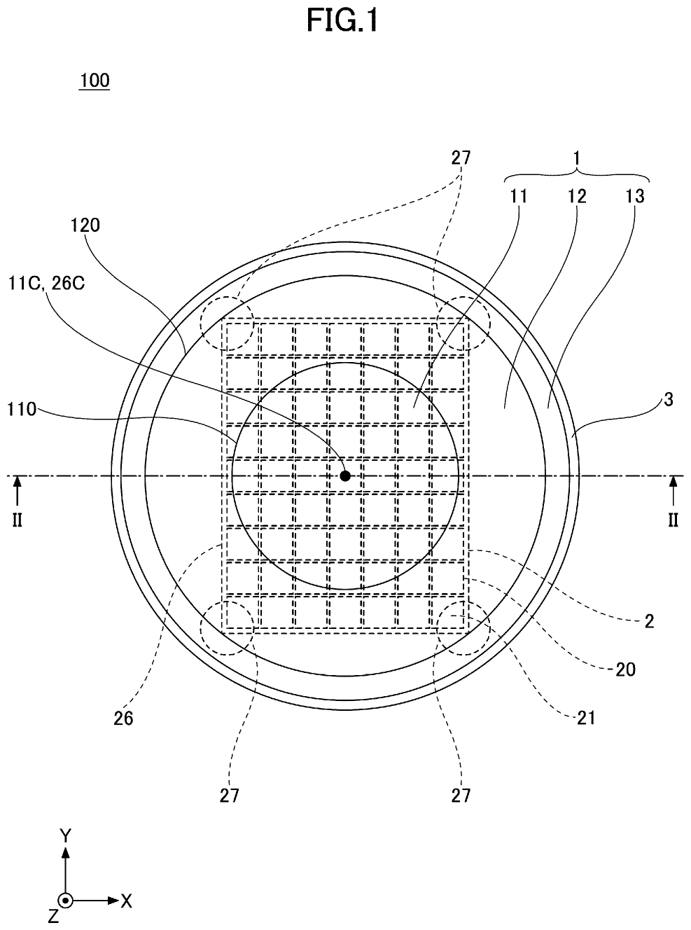

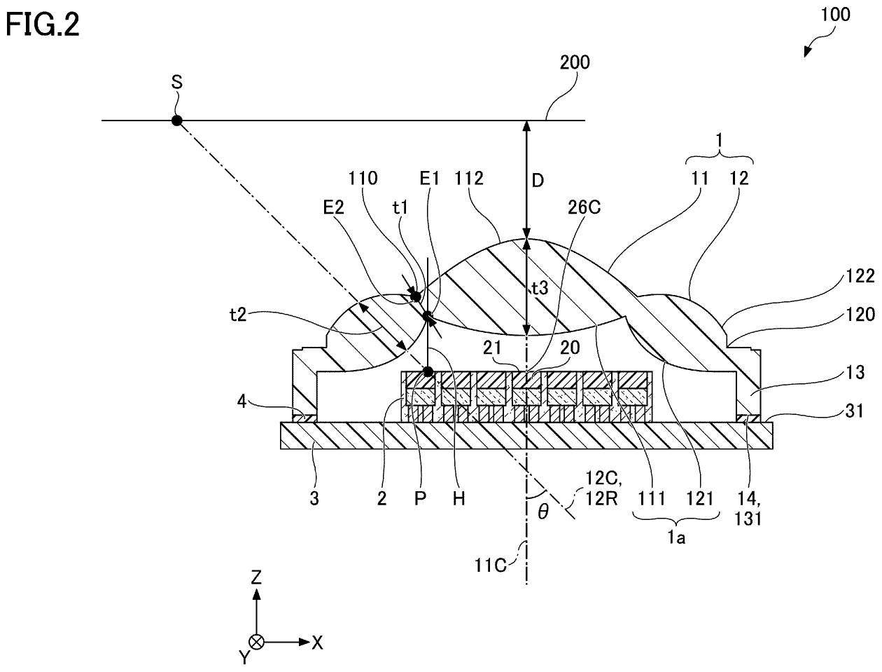

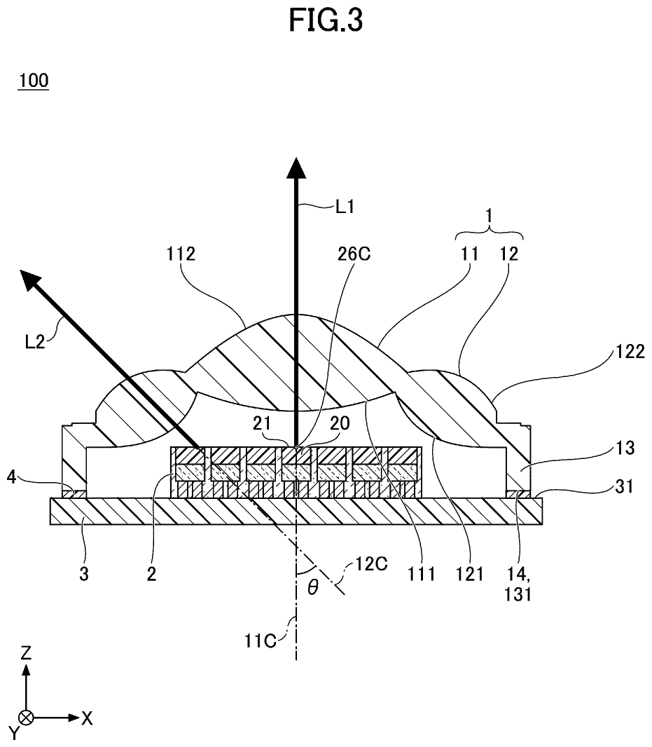

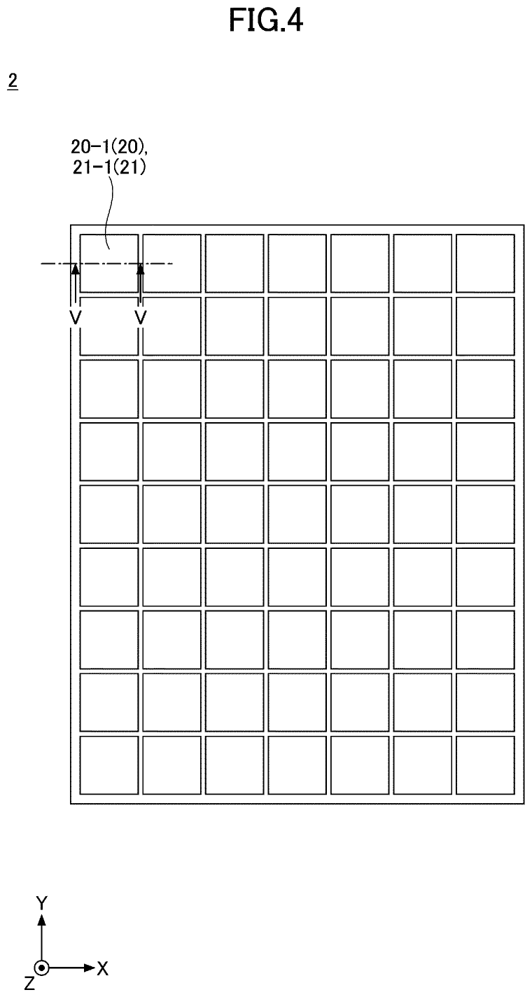

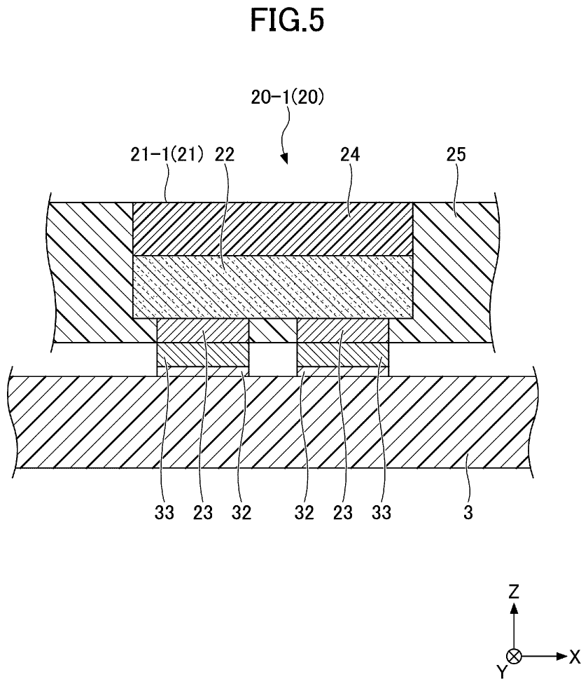

A configuration of a light-emitting module including a lens according to a first embodiment is described with reference to FIGS. 1 to 5. FIG. 1 is a schematic top view of a light-emitting module 100 including a lens 1 according to the first embodiment. FIG. 2 is a schematic cross-sectional view taken along line II-II in FIG. 1. FIG. 3 is a schematic cross-sectional view illustrating a behavior of light emitted from the light-emitting module 100. FIG. 4 is a schematic top view illustrating a configuration of a light source 2 in the light-emitting module 100. FIG. 5 is a schematic cross-sectional view taken along line V-V in FIG. 4.

The light-emitting module 100 is, for example, a light-emitting module for a flash light source in an imaging device provided in a smartphone. Examples of the imaging device include a camera for shooting a still image, a video camera for shooting a moving image, and the like.

As illustrated in FIGS. 1 and 2, the light-emitting module 100 includes the lens 1 and the light source 2. The lens 1 has a first surface 1a including a first light incident surface 111 and a second light incident surface 121. The light source is disposed facing the first surface 1a of the lens 1.

In the example illustrated in FIGS. 1 and 2, the light-emitting module 100 includes a substrate 3 on which the lens 1 and the light source 2 are disposed, and a first adhesive member 4 disposed between a lower surface 14 of the lens 1 and an upper surface 31 of the substrate 3. The lens 1 is bonded to the upper surface 31 of the substrate 3 by the first adhesive member 4. The light source 2 is mounted on the upper surface 31 of the substrate 3.

The lens 1 includes a first lens portion 11 having positive refractive power, and a second lens portion 12 having positive refractive power and located outward of an outer edge 110 of the first lens portion 11 in a top view. In the example illustrated in FIGS. 1 and 2, the lens 1 includes a leg portion 13 located outward of an outer edge 120 of the second lens portion 12 in a top view.

The “refractive power” indicates a degree to which the traveling direction of incident light is changed. The “positive refractive power” is refractive power for focusing light. The “negative refractive power” is a refractive power for diverging light. The degree to which the traveling direction of incident light is changed is not limited to being defined by refraction, and may be defined by an optical phenomenon other than refraction, such as diffraction or reflection. For example, when the first lens portion 11 includes a Fresnel lens, part of light incident on the Fresnel lens is reflected by a surface of a protrusion of the Fresnel lens to be bent in a desired direction. The refractive power further includes the degree to which the traveling direction of light is changed by such reflection.

In the lens 1, the first lens portion 11 is a portion having an optical axis 11C and including the first light incident surface 111 and a first light exit surface 112 located opposite to the first light incident surface 111. The optical axis 11C overlaps the light source 2 in a top view. Part of the light emitted from the light source 2 enters the first lens portion 11 from the first light incident surface 111, passes through the interior of the first lens portion 11, and then exits from the first light exit surface 112.

In the lens 1, the second lens portion 12 is a portion including the second light incident surface 121 and a second light exit surface 122 located opposite to the second light incident surface 121. In the example illustrated in FIG. 2, the second lens portion 12 supports the first lens portion 11. Part of the light emitted from the light source 2 enters the second lens portion 12 from the second light incident surface 121, passes through the interior of the second lens portion 12, and then exits from the second light exit surface 122. In the example illustrated in FIG. 2, the second lens portion 12 overlaps the light source 2 in a top view. As long as part of the light emitted from the light source 2 is affected by the second lens portion 12, the second lens portion 12 and the light source 2 do not necessarily need to overlap each other in a top view.

As illustrated in FIG. 2, in one cross section including the optical axis 11C, the second lens portion 12 has a lens main axis 12C. Here, the lens main axis 12C means an axis that can represent a typical behavior of light passing through the second lens portion 12. For example, in one cross section including the optical axis 11C, when the second lens portion 12 has the optical axis in the planes of the second light incident surface 121 and the second light exit surface 122, the lens main axis 12C of the second lens portion 12 is the optical axis of the second lens portion 12. The optical axis of second lens portion 12 is, for example, an axis passing through the center of curvature of the second light incident surface 121 and the center of curvature of the second light exit surface 122 in one cross section including the optical axis 11C. When the second light incident surface 121 or the second light exit surface 122 is an aspherical surface, the optical axis of second lens portion 12 may be an axis passing through the paraxial center of curvature. The paraxial center of curvature is the center of curvature of what is called a paraxial region, which is a region substantially spherical in the vicinity of the center axis of an aspherical surface. In addition, in one cross section including the optical axis 11C, when the second lens portion 12 has an optical axis outside the planes of the second light incident surface 121 and the second light exit surface 122 and not inside the planes thereof, the optical axis located outside the planes may be the lens main axis 12C of the second lens portion 12.

In the example illustrated in FIG. 1, the light source 2 has a substantially rectangular outer shape in a top view. The light source 2 includes a plurality of light-emitting units 20. The light source 2 includes 63 light-emitting units 20 each having a substantially rectangular light-emitting surface 21. The 63 light-emitting units 20 are disposed in a matrix of 9 rows and 7 columns. The light-emitting surface 21 refers to a main light extraction surface of the light-emitting unit 20. Therefore, the light-emitting surface 21 of the light-emitting unit 20 also serves as a light-emitting surface of the light source 2. A region including the light-emitting surface 21 corresponds to a light-emitting region 26. When there is only one light-emitting surface 21, the light-emitting region 26 is a region surrounded by the outer edge of the light-emitting surface 21. When the light source 2 includes a plurality of the light-emitting surfaces 21, the light-emitting region 26 is a region connecting outer edges of the light-emitting surfaces 21 located on the outer side in a top view. In the example illustrated in FIG. 1, the light-emitting region 26 includes 63 light-emitting surfaces 21. The shape of the outer edge of the light-emitting region 26 is substantially rectangular in a top view and includes four corner portions 27. In the present embodiment, a center 26C of the light-emitting region 26 overlaps the optical axis 11C in a top view. The light source 2 emits light from the light-emitting surface 21 included in each of the plurality of light-emitting units 20 in a direction in which the first lens portion 11 is located. The number of the light-emitting units 20 included in the light source 2 is not limited to 63, and may be any number as long as at least one light-emitting unit 20 is included.

The plurality of light-emitting units 20 can be individually driven to emit light. By controlling the distribution of the current to be supplied to each of the plurality of light-emitting units 20, the light distribution of the light emitted from the light-emitting module 100 can be controlled.

The light-emitting module 100 may turn on the plurality of light-emitting units 20 individually or on a group-by-group basis. The light-emitting module 100 can achieve a high contrast of the irradiation light on the irradiation plane irradiated with the light from the light source 2 by turning on the plurality of light-emitting units 20 individually or on a group-by-group basis, with a desired brightness. In addition, the light-emitting module 100 can implement partial irradiation of the irradiation plane by turning on the plurality of light-emitting units 20 individually or on a group-by-group basis. The “partial irradiation” refers to partially irradiating part of the region of the irradiation plane with light.

With the partial irradiation, a partial region of the irradiation plane is irradiated with light. Therefore, to make light with which a desired region is irradiated stand out, the irradiation light preferably has a clear outer edge. That is, preferably, there is a large difference in illuminance of irradiation light between a desired region to be irradiated with light and a region other than the desired region. In other words, in the desired region of the irradiation plane to be irradiated with light, the amount of stray light around the irradiation light is preferably small. Note that the irradiation light means controlled light. The stray light means uncontrolled light that is not intended by design. In the light-emitting module 100, by reducing the stray light on the irradiation plane, a desired region is irradiated with light, and light with which a region other than the desired region is irradiated is reduced. Thus, a large difference in illuminance of irradiation light between the desired region to be irradiated with light and the region other than the desired region is achieved, whereby the light with which the desired region is irradiated can stand out. In other words, a high contrast of the irradiation light on the irradiation plane can be achieved.

When the light-emitting module 100 is used as a flash light source of an imaging device, for example, light to be emitted from the light-emitting module 100 can be switched between a wide-angle mode and a narrow-angle mode. In the present embodiment, the wide-angle mode is a mode in which all the light-emitting units 20 emit light, and the narrow-angle mode is a mode in which only the light-emitting units 20 located in the center and the vicinity thereof of the light-emitting region 26 emit light and the light-emitting units 20 located in the outer edge and the vicinity thereof of the light-emitting region 26 do not emit light. A light distribution angle in the narrow-angle mode is less than that in the wide-angle mode. Because the light-emitting module 100 can switch irradiation light in accordance with the wide-angle mode and the narrow-angle mode, for example, photographing according to a photographing mode such as close-up photographing or telescopic photographing can be performed with the imaging device using the light emitted from the light-emitting module 100.

Here, in the light-emitting module, part of light emitted from the light source may pass through a portion of the lens other than the first lens portion around the first lens portion without being affected by the first lens portion, and thus may become stray light. For example, in a region where the light source and the first lens portion do not overlap each other in a top view, such as a region in the vicinity of an outer edge of the light source, light emitted from the vicinity of the outer edge of the light source passes through a portion other than the first lens portion and thus is likely to become stray light. The stray light generated leads to a non-uniform illuminance distribution of the irradiation light, or irradiation of a region other than a region desired to be partially irradiated with the light in the partial irradiation, resulting in a compromised quality of the irradiation light of the light-emitting module.

The light-emitting module 100 emits light L. In the light L, light that passes through the first lens portion 11 and is emitted as the irradiation light of the light-emitting module 100 is referred to as light L1. In the light L, light that is hardly affected by the first lens portion 11 is referred to as light L2. In the present embodiment, as illustrated in FIG. 2, in one cross section including the optical axis 11C, the lens main axis 12C is inclined with respect to the optical axis 11C so as to have an increasing distance from the optical axis 11C toward the second light exit surface 122 from the second light incident surface 121. In the example illustrated in FIG. 2, the lens main axis 12C is inclined at an angle θ with respect to the optical axis 11C. Thus, as illustrated in FIG. 3, the light L2 that does not pass through the first lens portion 11 travels in a direction away from the light L1 that passes through the first lens portion 11 in accordance with the inclination of the lens main axis 12C. The light L2 is light that can become stray light when it is not affected by the first lens portion 11 or the second lens portion 12. In the present embodiment, by controlling the light L2 with the second lens portion 12, it is possible to reduce the uncontrolled light in the light L and reduce the stray light from the light-emitting module 100. For example, in the example illustrated in FIG. 2, as will be described below in relation to the effect of reducing stray light, the stray light is reduced by controlling the irradiation direction of the light L2 so as to increase the distance between the light L1 passing through the first lens portion 11 and the light L2. Thus, with the present embodiment, the lens 1 that reduces stray light can be provided. Furthermore, with the present embodiment, the light-emitting module 100 that reduces stray light can be provided.

In the present embodiment, the inclination of the lens main axis 12C with respect to the optical axis 11C can be set in a range from 30 degrees to 50 degrees. In the example illustrated in FIG. 2, the second lens portion 12 is provided in contact with the outer edge of the first lens portion 11. Under this condition, in one cross section including the optical axis 11C, a boundary light beam 12R emitted from a light-emitting point P of the light sources 2 located immediately below a boundary E1 between the first lens portion 11 and the second lens portion 12 (specifically, the boundary E1 between the first light incident surface 111 and the second light incident surface 121) in the direction along the optical axis 11C can exit the second light exit surface 122 at an angle in a range from 30 degrees to 50 degrees with respect to optical axis 11C so as to have an increasing distance from the optical axis 11C. In other words, the light-emitting point P is an intersection point between a straight line H, along the optical axis 11C, extending from the boundary E1 between the first lens portion 11 and the second lens portion 12 (specifically, the boundary E1 between the first light incident surface 111 and the second light incident surface 121) and a plane parallel to the light-emitting surface 21 of the light sources 2. The boundary between the first light exit surface 112 and the second light exit surface 122 is referred to as a boundary E2. The boundary light beam 12R is a light beam passing through a peak point S at which the illuminance of the irradiation light from the light-emitting point P is maximized on an irradiation plane 200 that is orthogonal to the optical axis 11C and located above the lens 1. In FIG. 2, because the boundary light beam 12R overlaps the lens main axis 12C, they are marked together with their reference characters. As illustrated in FIG. 2, when the second lens portion 12 is provided in contact with the outer edge of the first lens portion 11, the light L2 travels in a direction away from the light L1 when the above-described conditions are satisfied. As a result, the light L2 is controlled with the second lens portion 12, and thus the uncontrolled light in the light L is reduced, and stray light from the light-emitting module 100 is reduced. The second lens portion 12 may be provided without being in contact with the outer edge of the first lens portion 11. When there is a connecting portion between the first lens portion 11 and the second lens portion 12, the light-emitting point P under this condition is an intersection point between a straight line, along the optical axis 11C, extending from the center of the connecting portion and a plane parallel to the light-emitting surface 21 of the light sources 2.

The irradiation plane 200 is, for example, a plane that is located 150 mm above the light-emitting module 100 and is orthogonal to the optical axis 11C. In the example illustrated in FIG. 2, a distance D from the light-emitting module 100 to the irradiation plane 200 corresponds to 150 mm. The boundary light beam 12R is identified as a light beam passing through the peak point S and the light-emitting point P on the irradiation plane 200.

Each component of the light-emitting module 100 will be described in detail below.

### Lens 1

The lens 1 includes at least one of a resin material, such as a polycarbonate resin, an acrylic resin, a silicone resin, or an epoxy resin, and a glass material, which have transmissivity to the light emitted from the light source 2. The first lens portion 11, the second lens portion 12, and the leg portion 13 are connected to each other to be an integrated member. However, the first lens portion 11, the second lens portion 12, and the leg portion 13 may be distinct members. In addition, the leg portion 13 may be omitted, and the second lens portion 12 may also function as the leg portion 13. Note that the “transmissivity” in the lens 1 refers to a property that allows 60% or more of light incident on the light source 2 to be transmitted.

In the example illustrated in FIG. 1, the first lens portion 11 has a substantially circular outer shape in a top view. However, the outer shape of the first lens portion 11 in a top view is not limited to a substantially circular shape, and may be a substantially rectangular shape, a substantially elliptical shape, a substantially polygonal shape, or the like. In addition, the first lens portion 11 may have a rotationally symmetrical outer shape in a top view. Taking into account that the image capture area of a typical imaging device has a substantially rectangular shape, the first lens portion 11 may have a four-fold rotationally symmetrical shape or a two-fold rotationally symmetrical shape in a top view.

In the example illustrated in FIG. 2, the first light incident surface 111 is a convex surface that is convex on the side where the light source 2 is located. The first light exit surface 112 is a convex surface that is convex on the side opposite to the side where the light source 2 is located. The first lens portion 11 is a biconvex single lens. Each of the first light incident surface 111 and the first light exit surface 112 is a spherical surface. However, as long as the first lens portion 11 has a positive refractive power, the first light incident surface 111 may be a concave surface that is concave on the side where the light source 2 is located, and the first light exit surface 112 may be a concave surface that is concave on the side opposite to the side where the light source 2 is located. The first lens portion 11 may be a single meniscus lens. The first light incident surface 111 and the first light exit surface 112 are not limited to spherical surfaces, and may be aspherical surfaces. Further, each of the first light incident surface 111 and the first light exit surface 112 may be a Fresnel lens surface.

In the example illustrated in FIG. 3, the light L1 from the light source 2 is converged by the first light incident surface 111 and the first light exit surface 112 at a focal point that overlaps the center 26C of the light-emitting region 26 in a top view, and then is emitted onto the irradiation plane as diverging light. The first lens portion 11 including a convex lens has a focal point on the +Z side of first lens portion 11, and the light L1 from each of the plurality of light-emitting units 20 travels toward the optical axis 11C of the first lens portion 11, converges, and then spreads. That is, the light from each light-emitting unit 20 travels in a direction symmetrical to the position of the corresponding light-emitting unit 20 with respect to a point on the optical axis 11C. Note that the light from each light-emitting unit 20 does not need to strictly pass through a point on the optical axis 11C. Thus, for example, when the light-emitting module 100 is mounted on a smartphone or the like, blocking of the light L1 emitted from the light-emitting module 100 by the housing of the smartphone or the like can be reduced. Then, the light L1 from the light sources 2 can be efficiently emitted through the first lens portion 11.

In the present embodiment, as illustrated in FIG. 1, the second lens portion 12 has an annular shape in a top view. In the example illustrated in FIG. 1, the second lens portion 12 has a continuous circular ring shape in a top view. Thus, stray light is reduced in almost all azimuth directions of rotational axis symmetry with the optical axis 11C as the center of rotation. However, the shape of the second lens portion 12 is not limited to a circular ring shape in a top view, and may be a rectangular ring shape or a polygonal ring shape. In addition, the second lens portion 12 need not be continuous but may have an intermittent annular shape in a top view. The intermittently annular second lens portion 12 refers to, for example, a form in which a plurality of lens portions are directly or indirectly connected to form an annular shape in a top view. In addition, the second lens portion 12 is not limited to having an annular shape in a top view, and may have a non-annular shape. The non-annular shape means a state in which the second lens portion 12 is partially provided on part of the outer side of the outer edge 110 of the first lens portion 11.

In the present embodiment, as illustrated in FIG. 2, a thickness t1 between the boundaries E1-E2 between the first lens portion 11 and the second lens portion 12 is less than a maximum thickness t2 of the second lens portion 12. When the lens 1 satisfies this condition, the light L2 is suitably away from the light L1, whereby the stray light from the light-emitting module 100 is suitably reduced. The thickness t1 between the boundaries E1-E2 is a thickness providing sufficient strength when the lens 1 is molded. For example, a maximum thickness t3 of the first lens portion 11 is 1.23 mm, and the thickness t1 between the boundaries E1-E2 is 0.31 mm.

In the example illustrated in FIG. 1, the leg portion 13 is a portion that supports the first lens portion 11 and the second lens portion 12. In the example illustrated in FIG. 2, the leg portion 13 has a lower surface 131 faces the upper surface 31 of the substrate 3 and bonded to the upper surface 31 of the substrate 3 via the first adhesive member 4. In the present embodiment, the lower surface 131 of the leg portion 13 is the lower surface 14 of the lens 1. The leg portion 13 has a continuous circular ring shape in a top view. However, the shape of the leg portion 13 is not limited to a circular ring shape in a top view, and may be a rectangular ring shape or a polygonal ring shape. In addition, the leg portion 13 may include a plurality of leg portions 13, and the plurality of leg portions 13 may be annularly disposed in a top view.

### Light Source 2

The light source 2 will be described with reference to FIGS. 4 and 5. The light source 2 includes 63 light-emitting units 20 each having the light-emitting surface 21. The 63 light-emitting units 20 are disposed vertically, horizontally, or in a matrix in a top view. In the example illustrated in FIG. 4, seven light-emitting units 20 are aligned along the X axis, and nine light-emitting units 20 are aligned along the Y axis. In FIG. 4, to avoid complication of the drawing, only a light-emitting unit 20-1 disposed at the first row and the first column among the 63 light-emitting units 20 and a light-emitting surface 21-1 are denoted by reference characters. The 63 light-emitting units 20 have the same configuration. Thus, FIG. 5 representatively illustrates a cross section of the light-emitting unit 20-1.

Each of the 63 light-emitting units 20 emits light toward the lens 1 provided above the light source 2, from the light-emitting surface 21.

The light source 2 has the light-emitting surface 21 in the upper surface, and is disposed on a +Z side surface of the substrate 3 with a surface opposite to the light-emitting surface 21 being a mounting surface. As illustrated in FIG. 5, the light-emitting unit 20-1 includes a light-emitting element 22, a wavelength conversion member 24 disposed above the light-emitting element 22, and a covering member 25 covering each of a lateral surface of the light-emitting element 22 and a lateral surface of the wavelength conversion member 24. Each of the lateral surface of the light-emitting element 22 and the lateral surface of the wavelength conversion member 24 is covered with the covering member 25. With this configuration, light leaking from the lateral surface of the light-emitting element 22 and the lateral surface of the wavelength conversion member 24 is reduced, so that light can be efficiently extracted from the light-emitting surface 21-1, whereby the light extraction efficiency of the light-emitting unit 20-1 is improved.

Because the light-emitting unit 20-1 includes the light-emitting element 22 and the wavelength conversion member 24, the light-emitting unit 20-1 can emit mixed-color light including a color of light emitted from the light-emitting element 22 and a color of light emitted from the wavelength conversion member 24. In the light-emitting unit 20-1, a degree of freedom in a color of light emitted from the light-emitting unit 20-1 can be increased by a combination of the light-emitting element 22 and the wavelength conversion member 24.

The covering member 25 integrally holds a plurality of the light-emitting elements 22 and a plurality of the wavelength conversion members 24. In the example illustrated in FIG. 5, the covering member 25 is disposed between adjacent light-emitting elements 22 and between adjacent wavelength conversion members 24. Accordingly, the covering member 25 integrally holds the 63 light-emitting elements 22 respectively included in the 63 light-emitting units 20 and the 63 wavelength conversion members 24 respectively included in the 63 light-emitting units 20.

Because the light source 2 includes the plurality of light-emitting units 20, the degree of freedom in the pattern of light that can be emitted from the light source 2 is improved. With the covering member 25 integrally holding the plurality of light-emitting elements 22 and the plurality of wavelength conversion members 24, the light source 2 can be easily mounted.

The light-emitting element 22 includes at least a pair of positive and negative electrodes 23 on the surface on the side opposite to the light-emitting surface 21 (that is, the lower surface).

The light-emitting element 22 contains various semiconductors such as a group III-V compound semiconductor and a group II-VI compound semiconductor. As the semiconductor, preferably, a nitride-based semiconductor such as In_{X}Al_{Y}Ga_{1-X-Y}N (0≤X, 0≤Y, X+Y≤1) is used, and any of InN, AlN, GaN, InGaN, AlGaN, InGaAlN, and the like can also be used. The light-emitting element 22 is an LED or a laser diode (LD), for example. A light emission peak wavelength of the light-emitting element 22 is preferably in a range from 400 nm to 530 nm, more preferably in a range from 420 nm to 490 nm, even more preferably in a range from 450 nm to 475 nm from the viewpoints of light emission efficiency, excitation of a wavelength conversion substance described below, and the like.

The wavelength conversion member 24 is, for example, a member having a substantially rectangular shape in a top view. The wavelength conversion member 24 is provided so as to cover an upper surface of the light-emitting element 22. The wavelength conversion member 24 contains a wavelength conversion substance that converts a wavelength of at least part of light from the light-emitting element 22. The wavelength conversion member 24 can be formed using a light-transmissive resin material or an inorganic material such as ceramic or glass. As the resin material, a thermosetting resin, such as a silicone resin, a silicone modified resin, an epoxy resin, an epoxy modified resin, or a phenol resin, can be used. Particularly, a silicone resin or a modified resin thereof with good light resistance and heat resistance is used. Transmissivity here preferably corresponds to 60% or more of the light from the light-emitting element 22 being transmitted. Further, as the wavelength conversion member 24, a thermoplastic resin, such as a polycarbonate resin, an acrylic resin, a methyl pentene resin, or a polynorbornene resin, can be used. The wavelength conversion member 24 may be, for example, a member containing a wavelength conversion substance in the resin material, ceramic, glass, or the like, and a sintered compact of a wavelength conversion substance. The wavelength conversion member 24 may contain a light diffusion substance described below in the resin described above. The wavelength conversion member 24 may include multiple layers including a resin layer containing a wavelength conversion substance or a light diffusion substance and disposed on a ±Z side surface of a sintered body of a resin, a ceramic, glass, or the like.

Examples of the usable wavelength conversion substance contained in the wavelength conversion member 24 include an yttrium aluminum garnet phosphor (for example, (Y,Gd)₃(Al,Ga)₅O₁₂:Ce), a lutetium aluminum garnet phosphor (for example, Lu₃(Al,Ga)₅O₁₂:Ce), a terbium aluminum garnet phosphor (for example, Tb₃(Al,Ga)₅O₁₂:Ce), a CCA phosphor (for example, Ca₁₀(PO₄)₆Cl₂:Eu), an SAE phosphor (for example, Sr₄Al₁₄O₂₅:Eu), a chlorosilicate phosphor (for example, Ca₈MgSi₄O₁₆Cl₂:Eu), a silicate phosphor (for example, (Ba,Sr,Ca,Mg)₂SiO₄:Eu), oxynitride phosphors such as a β-SiAlON phosphor (for example, (Si,Al)₃(O,N)₄:Eu) and an α-SiAlON phosphor (for example, Ca(Si,Al)₁₂(O,N)₁₆:Eu), nitride phosphors such as an LSN phosphor (for example, (La,Y)₃Si₆N₁₁:Ce), a BSESN phosphor (for example, (Ba,Sr)₂Si₅N₈:Eu), an SLA phosphor (for example, SrLiAl₃N₄:Eu), a CASN phosphor (for example, CaAlSiN₃:Eu), and an SCASN phosphor (for example, (Sr,Ca)AlSiN₃:Eu), fluoride phosphors such as a KSF phosphor (for example, K₂SiF₆:Mn), a KSAF phosphor (for example, K₂(Si₁₋ₓAlₓ)F₆₋ₓ:Mn, where x satisfies 0<x<1), and an MGF phosphor (for example, 3.5MgO·0.5MgF₂·GeO₂:Mn), quantum dots having a perovskite structure (for example, (Cs,FA,MA)(Pb,Sn)(F,Cl,Br,I)₃, where FA represents formamidinium and MA represents methylammonium), II-VI group quantum dots (for example, CdSe), III-V group quantum dots (for example, InP), quantum dots having a chalcopyrite structure (for example, (Ag,Cu)(In,Ga)(S,Se)₂), and the like.

The wavelength conversion substance described above is in the form of particles. Further, one type of these wavelength conversion substances can be used alone, or two or more types of these wavelength conversion substances can be used in combination.

In the present embodiment, the light-emitting unit 20 includes a blue LED as the light-emitting element 22, and the wavelength conversion member 24 contains a wavelength conversion substance for wavelength-converting the light emitted from the light-emitting element 22 into yellow light. Thus, the light source 2 including the light-emitting unit 20 emits white light. The wavelength or chromaticity of light emitted from the light source 2 may be appropriately selected in accordance with the intended use of the light-emitting module 100. The wavelength conversion member 24 contains a light diffusion substance. Examples of the light diffusion substance that can be used include titanium oxide, barium titanate, aluminum oxide, silicon oxide, and the like.

The covering member 25 is a member that covers the lateral surfaces of the light-emitting element 22 and the wavelength conversion member 24. The covering member 25 directly or indirectly covers the lateral surfaces of the light-emitting element 22 and the wavelength conversion member 24. An upper surface of the wavelength conversion member 24 in FIG. 5 is exposed from the covering member 25 and corresponds to the light-emitting surface 21 of the light-emitting unit 20. The covering member 25 is preferably constituted by a member having a high light reflectivity to improve light extraction efficiency. As the covering member 25, a resin material containing a light diffusion substance, such as white pigment, for example, can be used. Alternatively, the covering member 25 may be a light-reflective member composed of an inorganic material containing boron nitride and alkali metal silicate, for example. In this case, titanium oxide or zirconium oxide can be further contained.

Examples of the light diffusion substance contained in the covering member 25 include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. One type of these is preferably used alone, or a combination of two or more types thereof is preferably used. The resin material is preferably a material in which a resin material including a thermosetting resin, such as an epoxy resin, an epoxy modified resin, a silicone resin, a silicone modified resin, a phenol resin, or the like, as a main component is used as a base material. The covering member 25 may be constituted by a member having transmissivity or absorbency for visible light as necessary. The member having the light absorbency contains, for example, carbon black.

The light source 2 is electrically connected to a wiring 32 included in the substrate 3. The substrate 3 includes the wiring 32 disposed on a surface. The substrate 3 may include the wiring 32 therein. The light source 2 and the substrate 3 are electrically connected to each other by connecting a wiring 32 of the substrate 3 and at least the pair of positive and negative electrodes 23 of the light-emitting element 22 to each other via an electrically conductive member 33. The configuration, size, and the like of the wiring 32 of the substrate 3 are set according to the configuration and size of the electrode 23 of the light-emitting element 22.

### Substrate 3

The substrate 3 is a substrate including a wiring, on which the light source 2 can be mounted. In the example illustrated in FIG. 1, the substrate 3 is a plate-shaped member having a substantially circular shape in a top view. Note that the outer shape of the substrate 3 in a top view may be substantially rectangular, substantially elliptical, substantially polygonal, or the like. An electronic component other than the light source 2 may be further disposed on the substrate 3. The electronic component is a Zener diode, a thermistor, a capacitor, a light-receiving sensor, or the like.

For the substrate 3, an insulating material is preferably used as a base material, and a material through which the light emitted from the light source 2, external light, and the like are not readily transmitted is preferably used. In the present specification, the external light includes not only solar light but also all light incident from the outside of the light-emitting module 100 to the interior of the light-emitting module 100. Further, for the substrate 3, a material having a certain degree of strength is preferably used. Specifically, the substrate 3 can be formed using a ceramic, such as alumina, aluminum nitride, mullite, or silicon nitride, or a resin, such as a phenol resin, an epoxy resin, a polyimide resin, a bismaleimide triazine resin (BT resin), a polyphthalamide, or a polyester resin, as the base material.

The wiring 32 can be made of at least one type of copper, iron, nickel, tungsten, chromium, aluminum, silver, gold, titanium, palladium, rhodium, or an alloy thereof. Furthermore, a layer of silver, platinum, aluminum, rhodium, gold, or an alloy thereof may be provided on the surface layer of the wiring 32 to enhance at least one of the wettability of the electrically conductive member 33 and light reflectivity of the wiring 32.

Effect of Reducing Stray Light from Light-Emitting Module 100

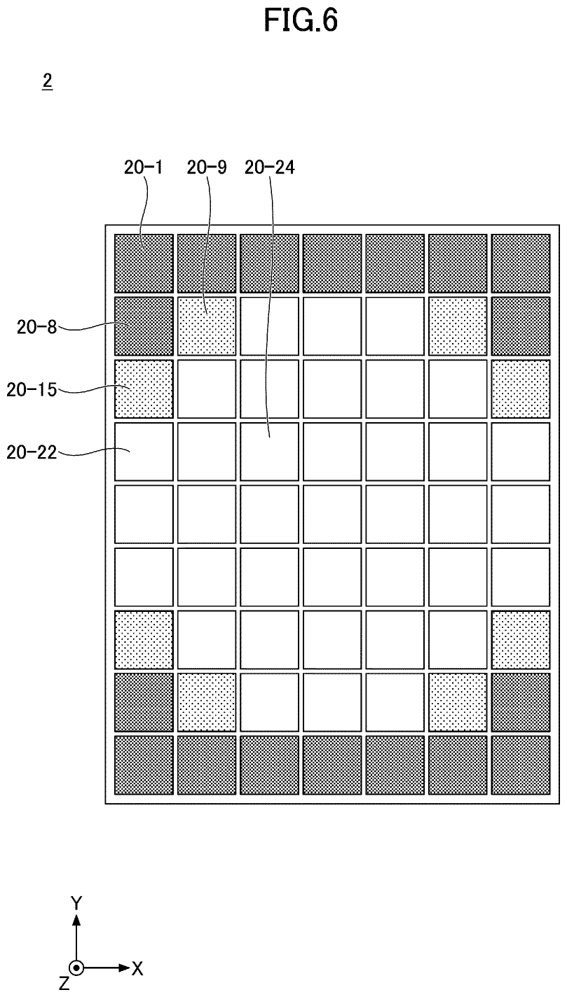

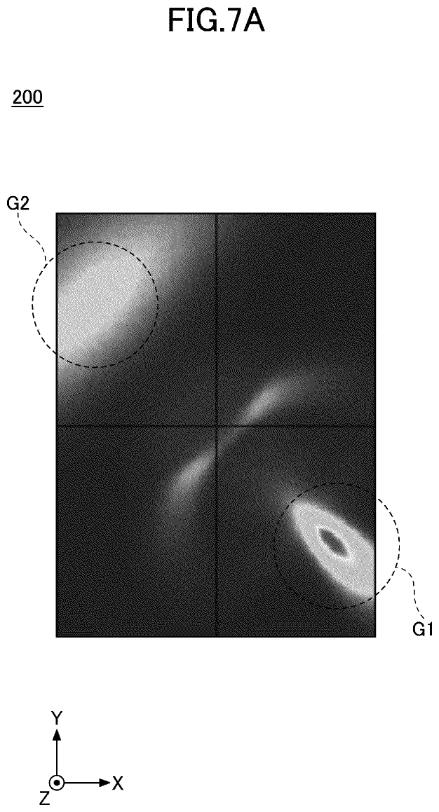

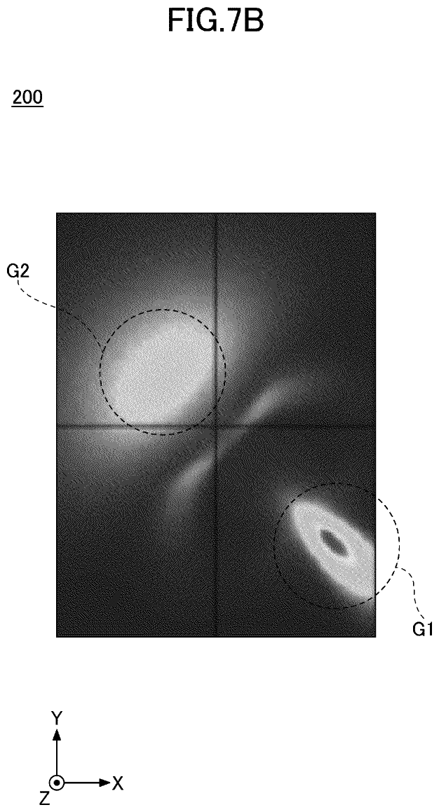

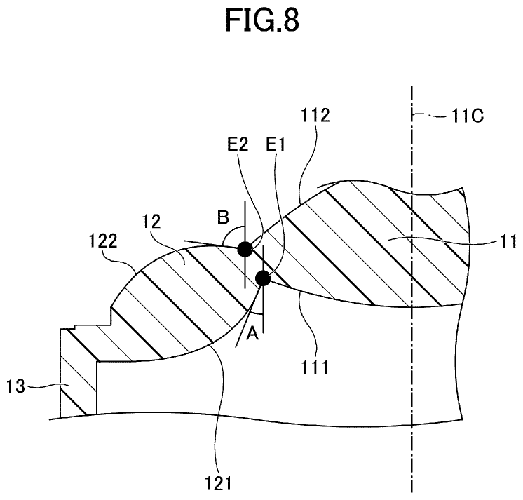

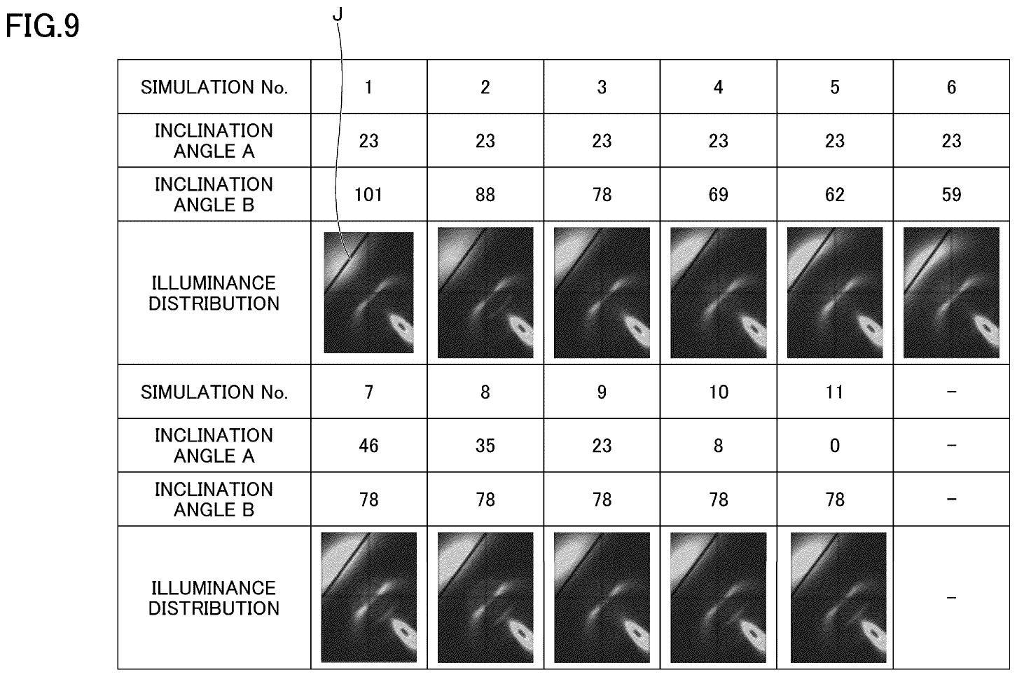

An effect of reducing stray light from the light-emitting module 100 will be described with reference to FIGS. 6 to 9. FIG. 6 is a schematic view illustrating a likelihood of generation of stray light at each of the positions of the light-emitting units 20 in the light-emitting module 100. FIG. 7A is a diagram showing an illuminance distribution in a case in which one light-emitting unit 20 that is likely to generate stray light is caused to emit light in the light-emitting module 100. FIG. 8 is a schematic cross-sectional view illustrating inclination angles of the second light incident surface 121 and the second light exit surface 122 at the boundary E1 between the first lens portion 11 and the second lens portion 12 of the lens 1. FIG. 9 is a diagram showing a relationship between an illuminance distribution in a case in which only one light-emitting unit 20 with which stray light is likely to be produced is caused to emit light in the light-emitting module 100, and the inclinations of the second light incident surface 121 and the second light exit surface 122 in FIG. 8.

In FIG. 6, the likelihoods of generation of stray light by 63 light-emitting units 20 are represented by the types of hatching. The light-emitting unit 20 indicated by thick dot hatching is a light-emitting unit located at the outermost edge of the light source 2 and having high likelihood of generation of stray light. In the example illustrated in FIG. 6, the light-emitting units 20 indicated by thick dot hatching correspond to a total of 18 light-emitting units 20 including seven light-emitting units in the first row, two light-emitting units at the second row and the first column and at the second row and the seventh column, two light-emitting units at the eighth row and the first column and at the eighth row and the seventh column, and seven light-emitting units in the ninth row. For example, the light-emitting unit 20-1 at the first row and the first column and the light-emitting unit 20-8 at the second row and the first column are light-emitting units having high likelihood of generation of stray light. The light-emitting unit 20 indicated by thin dot hatching is located on the slightly inner side with respect to the outermost edge of the light source 2 and is a light-emitting unit having relatively high likelihood of generation of stray light. In the example illustrated in FIG. 6, the light-emitting units 20 indicated by thin dot hatching correspond to a total of eight light-emitting units 20 including two light-emitting units at the second row and the second column and at the second row and the sixth column, two light-emitting units at the third row and the first column and at the third row and the seventh column, two light-emitting units at the seventh row and the first column and at the seventh row and the seventh column, and two light-emitting units at the eighth row and the second column and at the eighth row and the sixth column. For example, a light-emitting unit 20-9 at the second row and the second column and a light-emitting unit 20-15 at the third row and the first column are light-emitting units having relatively high likelihood of generation of stray light. The light-emitting unit 20 without hatching is a light-emitting unit having low likelihood of generation of stray light. In the example illustrated in FIG. 6, the light-emitting units 20 without hatching correspond to 37 light-emitting units 20 excluding the 18 light-emitting units 20 with thick dot hatching and the 8 light-emitting units 20 with thin dot hatching described above among the 63 light-emitting units 20. For example, a light-emitting unit 20-22 at the fourth row and the first column and a light-emitting unit 20-24 at the fourth row and the third column are light-emitting units having low likelihood of generation of stray light.

FIGS. 7A and 7B show simulation results of illuminance distribution obtained on the irradiation plane 200. FIG. 7A shows a simulation result of an illuminance distribution obtained on the irradiation plane 200 when only the light-emitting unit 20-8 among the 63 light-emitting units 20 in FIG. 6 is caused to emit light in the light-emitting module 100 including the lens 1 according to the first embodiment. FIG. 7B shows a simulation result of an illuminance distribution obtained on the irradiation plane 200 when only the light-emitting unit 20-8 among the 63 light-emitting units 20 in FIG. 6 is caused to emit light in a light-emitting module of Reference Example 1, which is different from the light-emitting module 100 only in the lens. The lens of the light-emitting module of Reference Example 1 differs from the lens 1 of the light-emitting module 100 in that the light-emitting module of Reference Example 1 does not include the second lens portion 12. FIGS. 7A and 7B show the irradiation plane 200 when viewed from the +Z side. A region G1 is an illuminance distribution region of irradiation light. A region G2 is an illuminance distribution region of stray light. In FIGS. 7A and 7B, a color in the drawings closer to white indicates a higher illuminance of the irradiation light, and a color in the drawings closer to black indicates a lower illuminance of the irradiation light. Note that when the entire circumference of the black region is surrounded by the white region, the illuminance of the black region is higher than that of the white region. Therefore, the black region surrounded by the white region in the region G1 had a higher illuminance than the white region.

In the light-emitting module 100 according to the first embodiment, the light L2 that may become stray light travels in a direction away from the light L1 passing through the first lens portion 11 in accordance with the inclination of the lens main axis 12C of the second lens portion 12. Therefore, the illuminance distribution region of the stray light shown in FIG. 7A was located far from the illuminance distribution region of the irradiation light, compared with the illuminance distribution region of the stray light shown in FIG. 7B. Further, the illuminance of the stray light was lower than the illuminance of the irradiation light in FIG. 7A. From these facts, it was found that, in the light-emitting module 100, with the light L2 controlled with the second lens portion 12, the stray light is reduced, and the uncontrolled light in the light Lis reduced.

FIG. 8 is an enlarged view of the vicinity of the boundary E1 between the first lens portion 11 and the second lens portion 12 in FIG. 2. FIG. 8 illustrates an inclination angle A of the second light incident surface 121 at the boundary E1 and an inclination angle B of the second light exit surface 122 at the boundary E2. The inclination angle A is an inclination angle of the second light incident surface 121 with respect to the optical axis 11C of the first lens portion 11. The inclination angle B is an inclination angle of the second light exit surface 122 with respect to the optical axis 11C of the first lens portion 11. Specifically, the inclination angle A is an angle formed by a straight line parallel to the optical axis 11C of the first lens portion 11 and a tangent line of the second light incident surface 121 of the second lens portion 12 extending from the boundary E1. The inclination angle B is an angle formed by a straight line parallel to the optical axis 11C of the first lens portion 11 and a tangent line of the second light exit surface 122 of the second lens portion 12 extending from the boundary E2.

FIG. 9 shows simulation results of an illuminance distribution obtained on the irradiation plane 200 when only the light-emitting unit 20-8 among the 63 light-emitting units 20 in FIG. 6 is caused to emit light, with the combination of the inclination angle A and the inclination angle B in FIG. 8 changed. The combinations of the inclination angle A and the inclination angle B were set 11 patterns shown in FIG. 9, which are referred to as simulation Nos. 1 to 11, respectively. The illuminance distribution of FIG. 9 shows the irradiation plane 200 when viewed from the +Z side. In the simulation shown in FIG. 9, the inclination angle A was changed by changing the curvature of the second light incident surface 121. Further, the inclination angle B was changed by changing the curvature of the second light exit surface 122. Simulation Nos. 1 to 6 are data obtained by changing the angle B in a range from 59 degrees to 101 degrees, with the angle A fixed to 23 degrees. Simulation Nos. 7 to 11 are data obtained by changing the angle A in a range from 0 degrees to 46 degrees, with the angle B fixed to 78 degrees. Each of the inclination angle A and the inclination angle B is an absolute value of an angle.

The relationship between density and illuminance, and the positions of irradiation light and stray light in the simulation shown in FIG. 9 are the same as those in the simulation result shown in FIG. 7A. The same applies to the relationship between the density and the illuminance, and to the positions of the irradiation light and the stray light, in the simulation result of the illuminance distribution described below. In FIG. 9, a boundary line J is for determining whether the stray light is reduced. In other words, with a higher ratio of the illuminance distribution region of the stray light located outside the boundary line J, stray light can be determined to be more reduced.

From the results of Nos. 7 to 11 in FIG. 9, it was found that, for the sake of reduction of stray light, the inclination angle A is preferably more than 0 degrees and less than 50 degrees, more preferably in a range from 5 degrees to 40 degrees, and even more preferably in a range from 15 degrees to 30 degrees. From the results of Nos. 1 to 6, it was found that the inclination angle B is preferably in a range from 60 degrees to 85 degrees, and more preferably in a range from 70 degrees to 80 degrees.

### Second Embodiment

Next, a light-emitting module including a lens structure according to a second embodiment will be described. The same names and reference characters as those in the previously described embodiment indicate the same or similar members or configurations, and detailed descriptions thereof are omitted as appropriate. This shall apply to the embodiments which will be described hereinafter.

### Configuration of Light-Emitting Module Including Lens Structure According to Second Embodiment

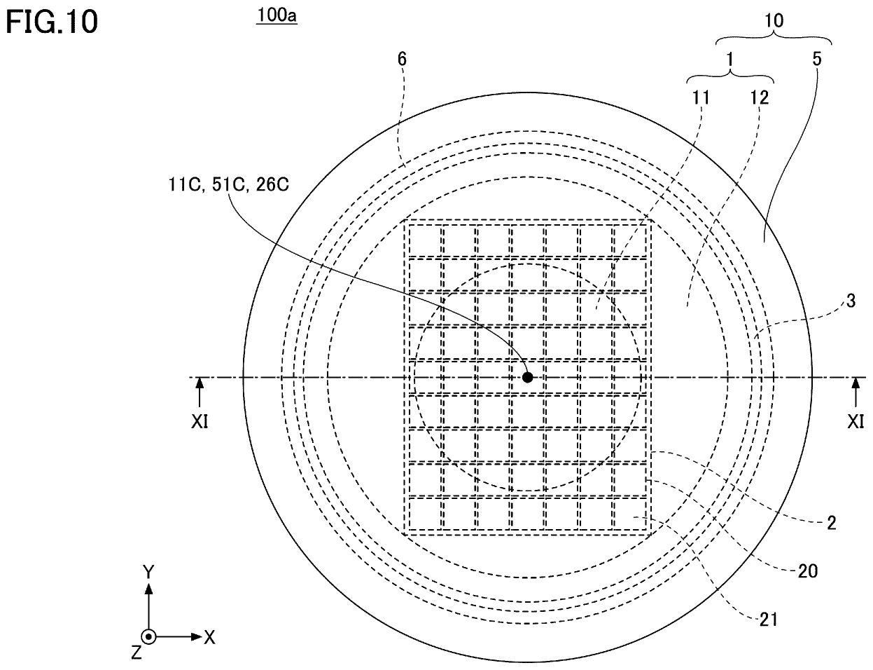

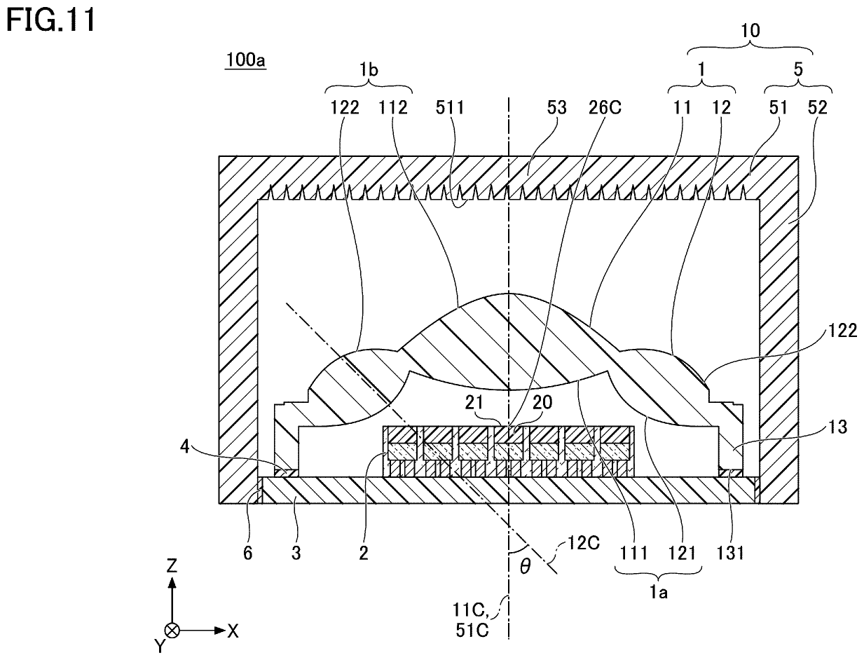

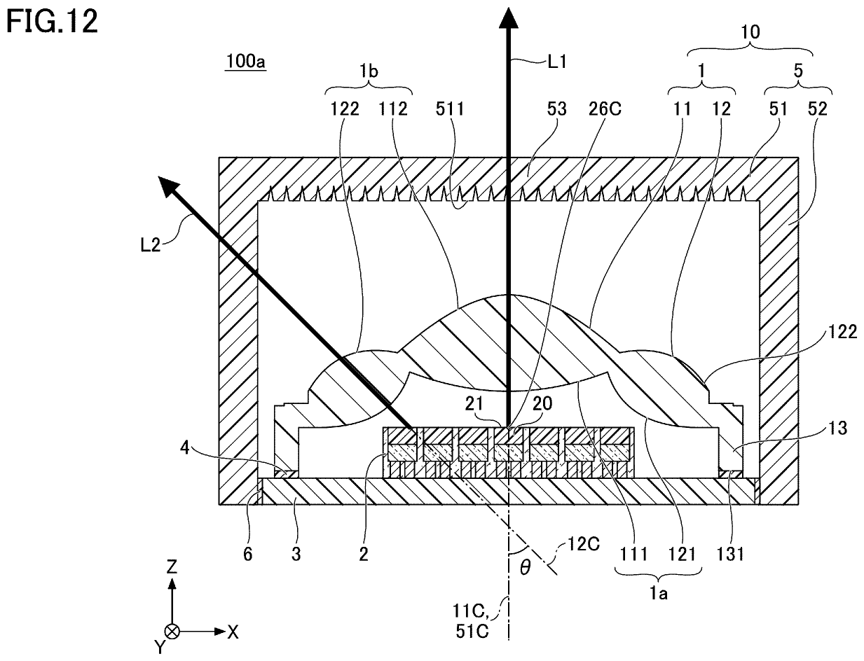

A configuration of a light-emitting module including a lens structure according to a second embodiment is described with reference to FIGS. 10 to 12. FIG. 10 is a schematic top view illustrating a light-emitting module 100a including a lens structure 10 according to the second embodiment. FIG. 11 is a schematic cross-sectional view taken along line XI-XI in FIG. 10. FIG. 12 is a schematic cross-sectional view illustrating the behavior of light emitted from the light-emitting module 100a.

The light-emitting module 100a according to the present embodiment is different from the light-emitting module 100 according to the first embodiment in that the lens structure 10 is included.

As illustrated in FIGS. 10 and 11, the lens structure 10 is a structure including the lens 1 and a light-transmissive member 5. The light-transmissive member 5 includes a third lens portion 51 disposed above the first lens portion 11 and the second lens portion 12, and a support portion 52 that supports the third lens portion 51. The lens 1 has the first surface 1a and a second surface 1b located on a side opposite to the first surface 1a. The second surface 1b has the first light exit surface 112 and the second light exit surface 122. The light-transmissive member 5 is disposed such that the third lens portion 51 faces the second surface 1b.

The light-transmissive member 5 is disposed so as to cover the lens 1. In the example illustrated in FIG. 10, the light-transmissive member 5 has a substantially circular outer shape in a top view. The outer shape of the light-transmissive member 5 in a top view may be a substantially elliptical shape, a substantially rectangular shape, a substantially polygonal shape, or the like.

The light-transmissive member 5 contains at least one of a resin material, such as a polycarbonate resin, an acrylic resin, a silicone resin, or an epoxy resin, and a glass material, which have transmissivity to the light emitted from the light source 2. The transmissivity of the third lens portion 51 is preferably a property in which 60% or more of the light from the light source 2 is transmitted.

In the example illustrated in FIG. 11, the third lens portion 51 and the support portion 52 are monolithic without using an adhesive member. From another viewpoint, the third lens portion 51 is connected to the support portion 52. Alternatively, the third lens portion 51 and the support portion 52 may be separate members joined with an adhesive member.

The third lens portion 51 transmits the light emitted from the light source 2 and transmitted through the lens 1. In the example illustrated in FIG. 11, the third lens portion 51 has, on a lower surface 511 thereof, protrusions 53 of concentric circle shapes centered on an optical axis 51C of the third lens portion 51. The optical axis 51C of the third lens portion 51 overlaps the optical axis 11C of the first lens portion 11 and the center 26C of the light-emitting region 26 in a top view. The protrusions 53 may be a Fresnel lens having a Fresnel shape. However, the third lens portion 51 is not limited to the Fresnel lens, and may be of other forms such as a biconvex single lens, a planoconvex single lens, a biconcave single lens, a planoconcave single lens, an array lens, a meniscus single lens, an aspherical lens, or a cylindrical lens.

Because the light-emitting module 100a includes the third lens portion 51, light distribution can be controlled by a combination of the lens 1 and the third lens portion 51. Thus, in the light-emitting module 100a, the degree of freedom in light distribution control is high, compared with a case in which only the lens 1 is included and the third lens portion 51 is not included.

The support portion 52 supports the third lens portion 51 such that the third lens portion 51 is disposed above the first lens portion 11 and the second lens portion 12. The support portion 52 is a portion, of the light-transmissive member 5, with a circular ring shape in a top view. The support portion 52 is provided outward of the substrate 3 so as to extend downward. The support portion 52 is disposed with part of the inner lateral surface facing the outer lateral surface of the substrate 3. The part of the inner lateral surface and the outer lateral surface of the substrate 3 are joined to each other with a second adhesive member 6. The light-transmissive member 5 and the substrate 3 are joined to each other by joining the support portion 52 and the substrate 3 to each other.

In the present embodiment, with the lens structure 10 including the lens 1, as illustrated in FIG. 12, the light L2 that does not pass through the first lens portion 11 travels in a direction away from the light L1 that passes through the first lens portion 11 in accordance with the inclination of the lens main axis 12C of the second lens portion 12. As described above, the light L2 is controlled with the second lens portion 12 so as to increase the distance between the light L1 passing through the first lens portion 11 and the light L2, whereby stray light is reduced. Thus, in the present embodiment, the lens structure 10 that reduces stray light can be provided. Further, in the present embodiment, it is possible to reduce stray light from the light-emitting module 100a including the lens structure 10.

In the present embodiment, as illustrated in FIG. 10, at least part of the light source 2 overlaps the second lens portion 12 in a top view. In the light L, the light emitted from the vicinity of the outer edge of the light source 2 includes a large proportion of the light L2 that is hardly affected by the first lens portion 11. In this case, most of the light L2 is likely to be stray light. Thus, with at least part of the light source 2, particularly, the outer edge including the corner portion 27 of the light source 2 overlapping the second lens portion 12 in a top view, the light L2 that is emitted from the light source 2 and passes through the second lens portion 12 travels away from the light L1 passing through the first lens portion 11, in accordance with the inclination of the lens main axis 12C. As a result, in the present embodiment, the light L2 can be controlled with the second lens portion 12 so as to increase the distance between the irradiation light from the light-emitting module 100a and the light L2. Thus, the stray light is reduced. The stray light can be reduced not only in a case in which the light source 2 includes the plurality of light-emitting units 20 but also in a case in which the light source 2 includes only one light-emitting unit 20.

Effect of Reducing Stray Light from Light-Emitting Module 100a

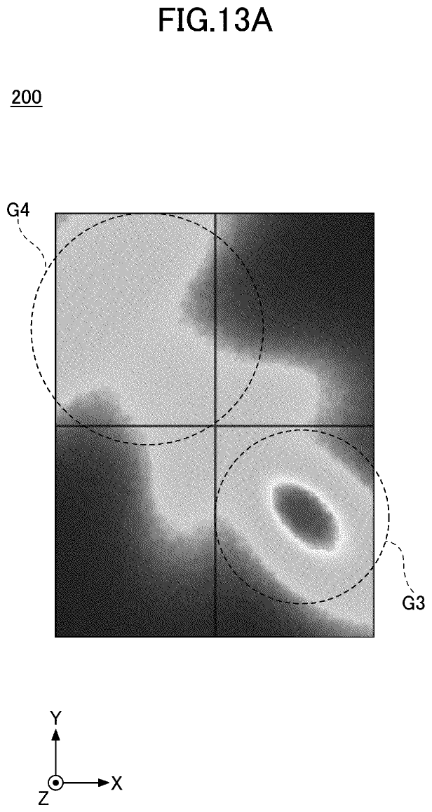

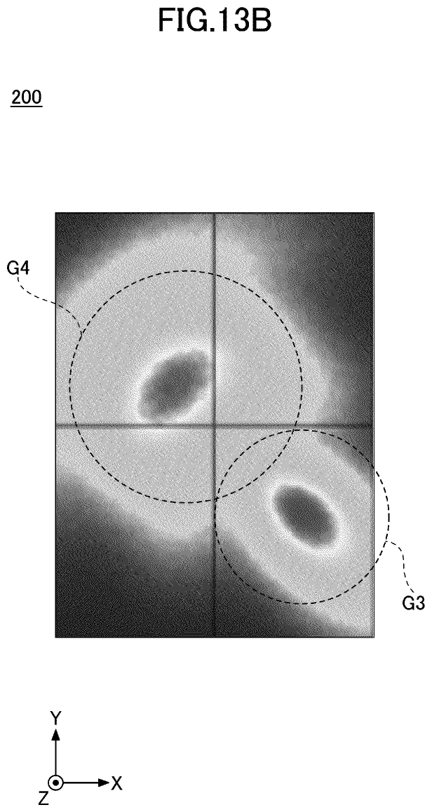

FIGS. 13A and 13B show simulation results of illuminance distribution obtained on the irradiation plane 200. FIG. 13A is a diagram showing an illuminance distribution when only one light-emitting unit 20 that is likely to generate stray light is caused to emit light, in the light-emitting module 100a including the lens structure 10 according to the second embodiment. FIG. 13A shows a simulation result of an illuminance distribution obtained on the irradiation plane 200 when only the light-emitting unit 20-8 among the 63 light-emitting units 20 in FIG. 6 is caused to emit light. FIG. 13B shows a simulation result of an illuminance distribution obtained on the irradiation plane 200 when only the light-emitting unit 20-8 among the 63 light-emitting units 20 in FIG. 6 is caused to emit light in a light-emitting module of Reference Example 2, which is different from the light-emitting module 100a only in the lens structure. The lens structure of the light-emitting module of Reference Example 2 differs from the lens structure 10 of light-emitting module 100a in that the lens does not include the second lens portion 12. FIGS. 13A and 13B show the irradiation plane 200 when viewed from the +Z side. A region G3 is an illuminance distribution region of irradiation light. A region G4 is an illuminance distribution region of stray light.

In the light-emitting module 100a according to the second embodiment, the light L2 travels in a direction away from light L1 passing through the first lens portion 11, in accordance with the inclination of the lens main axis 12C of the second lens portion 12. Therefore, the illuminance distribution region of the stray light shown in FIG. 13A was located far from the illuminance distribution region of the irradiation light, compared with the illuminance distribution region of the stray light shown in FIG. 13B. The illuminance of the black region surrounded by the white region in the region G3 was higher than that of the white region, and the illuminance of the stray light was lower than the illuminance of the irradiation light in FIG. 13A. From these facts, it was found that, in the light-emitting module 100a, with the light L2 controlled with the second lens portion 12, the stray light is reduced and the uncontrolled light in the light L is reduced.

### Third Embodiment

Next, a light-emitting module including a lens structure according to a third embodiment will be described.

### Configuration of Light-Emitting Module Including Lens Structure According to Third Embodiment

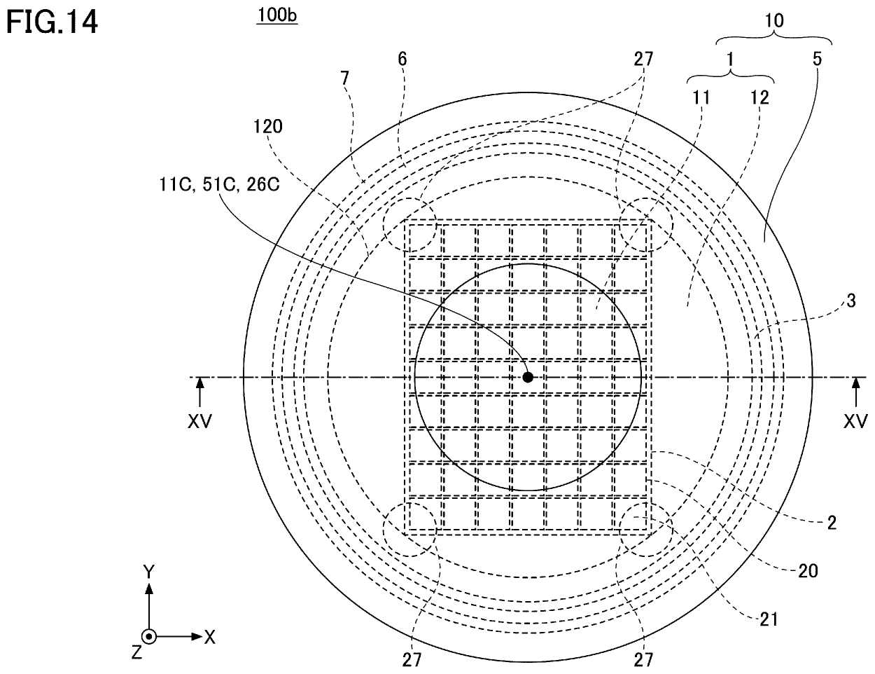

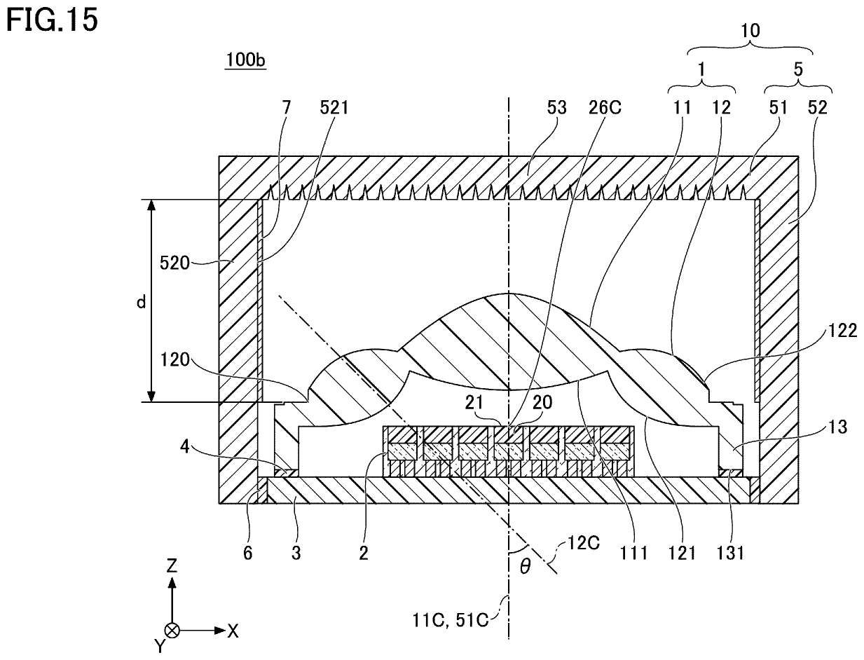

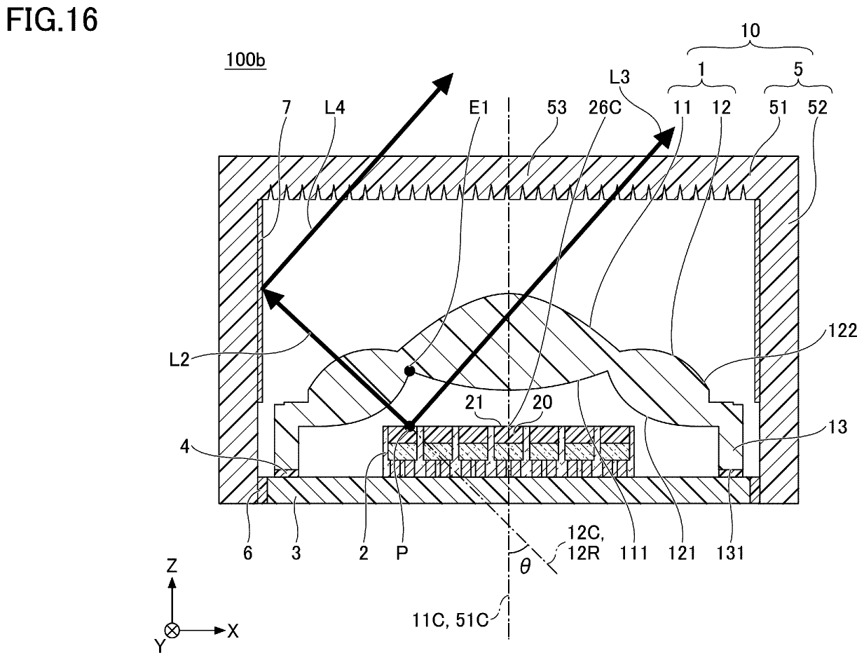

A configuration of the light-emitting module including the lens structure according to the third embodiment is described with reference to FIGS. 14 to 16. FIG. 14 is a schematic top view illustrating a light-emitting module 100b including the lens structure 10 according to the third embodiment. FIG. 15 is a schematic cross-sectional view taken along line XV-XV in FIG. 14. FIG. 16 is a schematic cross-sectional view illustrating the behavior of light emitted from the light-emitting module 100b.

The light-emitting module 100b according to the present embodiment is different from the light-emitting module 100a according to the second embodiment in that, in the lens structure 10, the support portion 52 has an inner lateral surface 521 facing the second light exit surface 122 and a reflection portion 7 is disposed on the inner lateral surface 521.

In the present embodiment, the reflection portion 7 is directly or indirectly joined to the inner lateral surface 521 of the support portion 52. The reflection portion 7 includes a metal film containing aluminum, gold, or the like, or a resin containing a light diffusion substance. The reflection portion 7 may include a metal multilayer film or the like. In the present embodiment, the inner lateral surface 521 facing the second light exit surface 122 includes a cylindrical portion 520. The cylindrical portion 520 is not limited to a strictly parallel cylindrical surface shape, and may have a tapered shape.

In the lens structure 10, the reflection portion 7 can be configured by adding a light diffusion substance to a base material such as a resin contained in the light-transmissive member 5, instead of joining a member different from the light-transmissive member 5 to the inner lateral surface 521 of the support portion 52 as described above. By adding the light diffusion substance to the resin contained in the light-transmissive member 5, high light reflectivity of the inner lateral surface 521 of the support portion 52 in the light-transmissive member 5 is achieved. Examples of the light diffusion substance that can be used include titanium oxide, barium titanate, aluminum oxide, silicon oxide, and the like. Also in such a configuration, the lens structure 10 can have the function of the reflection portion 7.

The second lens portion 12 is disposed inward of the reflection portion 7 in a top view. From another viewpoint, the reflection portion 7 is disposed outward of the outer edge 120 of the second lens portion 12 in a top view. In the example illustrated in FIG. 15, the reflection portion 7 is disposed entirely in a range d located above the position of the outer edge 120 of the second lens portion 12 in the inner lateral surface 521 of the support portion 52. Therefore, in the present embodiment, the reflection portion 7 has a cylindrical shape along the inner lateral surface 521 of the support portion 52. The reflection portion 7 may be disposed not only in the range d but also, for example, in a range located below the position of the outer edge 120 of the second lens portion 12 in the inner lateral surface 521 of the support portion 52.

The light-emitting module 100b emits the light L. In the light L, light that passes through the first lens portion 11 and is emitted as the irradiation light of the light-emitting module 100b is referred to as light L3. In the light L, light that is hardly affected by the first lens portion 11 is referred to as light L2. In the light L2, light affected by the reflection portion 7 and emitted as the irradiation light of the light-emitting module 100b is referred to as light L4. In the present embodiment, as illustrated in FIG. 16, the light L2 that does not pass through the first lens portion 11 passes through the second lens portion 12, is then reflected by the reflection portion 7, and becomes the light L4 that travels inward in a top view. By traveling inward in a top view, the light L4 travels in a direction along the light L3 passing through the first lens portion 11 and makes a contribution as the irradiation light from the light-emitting module 100b. As a result, in the present embodiment, it is possible to provide the lens structure 10, which enables a large amount of irradiation light from the light-emitting module 100b by reducing the stray light and utilizing the light which may become the stray light to change such light into the irradiation light. In addition, in the light-emitting module 100b including the lens structure 10, the amount of stray light is reduced and the amount of irradiation light is increased.

In the present embodiment, the light L4 is a portion of the boundary light beam 12R that has been emitted from the light-emitting point P of the light source 2, has passed through the second lens portion 12, and then has been reflected by the reflection portion 7. The boundary light beam 12R is emitted from the light-emitting point P located immediately below the boundary E1 between the first lens portion 11 and the second lens portion 12 in the direction along the optical axis 11C. The traveling direction of the light L4 is along the traveling direction of the light L3. The light L3 is a portion of the boundary light beam 12R, which has passed through the first lens portion 11. Thus, in the present embodiment, because the light L4 contributes to the light L3, the stray light is reduced and a large amount of irradiation light from the light-emitting module 100b is achieved. Note that “along” here means that an angle formed by a straight line along the traveling direction of the light beam of the light L4 reflected by the reflection portion 7 after passing through the second lens portion 12 and a straight line along the traveling direction of the light beam of the light L3 passing through the first lens portion 11 is +10 degrees or less. In addition, the surface of the reflection portion 7 facing the second lens portion 12 may be adjusted so as to be inclined with respect to the optical axis 11C and be along at least one of the traveling direction of the light L3 transmitted through the first lens portion 11 and the traveling direction of the light L1 described above.

Effect of Reducing Stray Light from Light-Emitting Module 100b

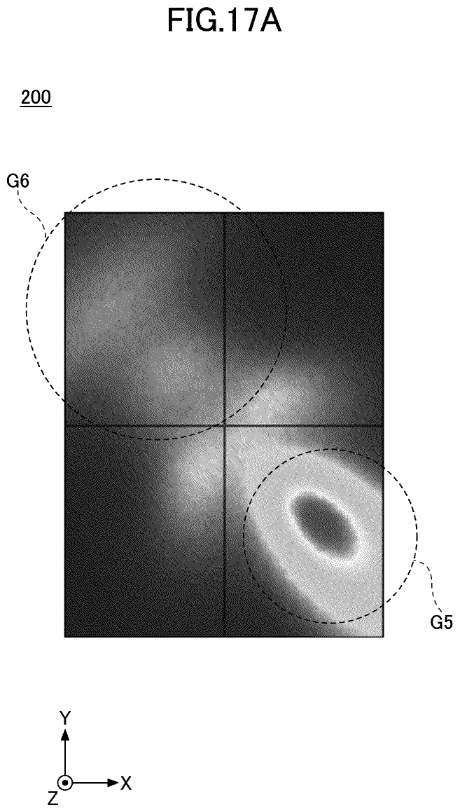

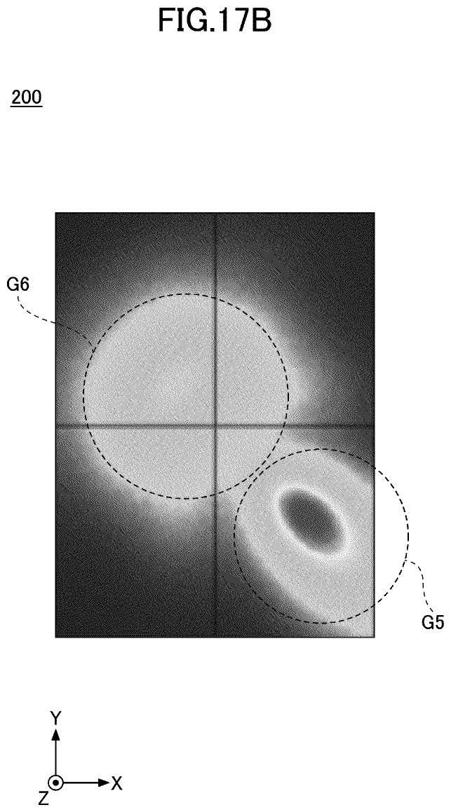

FIGS. 17A and 17B show simulation results of illuminance distribution obtained on the irradiation plane 200. FIG. 17A is a diagram showing an illuminance distribution when only one light-emitting unit 20 that is likely to generate stray light is caused to emit light, in the light-emitting module 100b including the lens structure 10 according to the third embodiment. FIG. 17A shows a simulation result of an illuminance distribution obtained on the irradiation plane 200 when only the light-emitting unit 20-8 among the 63 light-emitting units 20 in FIG. 6 is caused to emit light. FIG. 17B shows a simulation result of an illuminance distribution obtained on the irradiation plane 200 when only the light-emitting unit 20-8 among the 63 light-emitting units 20 in FIG. 6 is caused to emit light in a light-emitting module of Reference Example 3, which is different from the light-emitting module 100b only in the lens structure. The lens structure of the light-emitting module of Reference Example 3 differs from the lens structure 10 of light-emitting module 100b in that the lens does not include the second lens portion 12. FIGS. 17A and 17B show the irradiation plane 200 when viewed from the +Z side. A region G5 is an illuminance distribution region of irradiation light. A region G6 is an illuminance distribution region of stray light.

In the light-emitting module 100b according to the third embodiment, the light L2 travels in a direction away from light L3 passing through the first lens portion 11, in accordance with the inclination of the lens main axis 12C of the second lens portion 12. Therefore, the illuminance distribution region of the stray light shown in FIG. 17A was located far from the illuminance distribution region of the irradiation light, compared with the illuminance distribution region of the stray light shown in FIG. 17B. In addition, in the light-emitting module 100b, the light L2 is reflected by the reflection portion 7 to have the traveling direction changed, and thus becomes the light L4. Further, in the light-emitting module 100b, the traveling direction of the light L4 reflected by the reflection portion 7 is along the traveling direction of the light L3 transmitted through the first lens portion 11. Thus, the light L4 was included in the illuminance distribution region of the irradiation light indicated by the region G5. That is, like the light L3, the light L4 contributed as the irradiation light, and a large light amount of irradiation light was achieved. Therefore, in FIG. 17A, the illuminance of the stray light was lower than the illuminance of the irradiation light. This makes it possible to reduce the stray light from the light-emitting module 100b.

### Configuration of Light-Emitting Module Including Lens Structure According to Modification of Third Embodiment

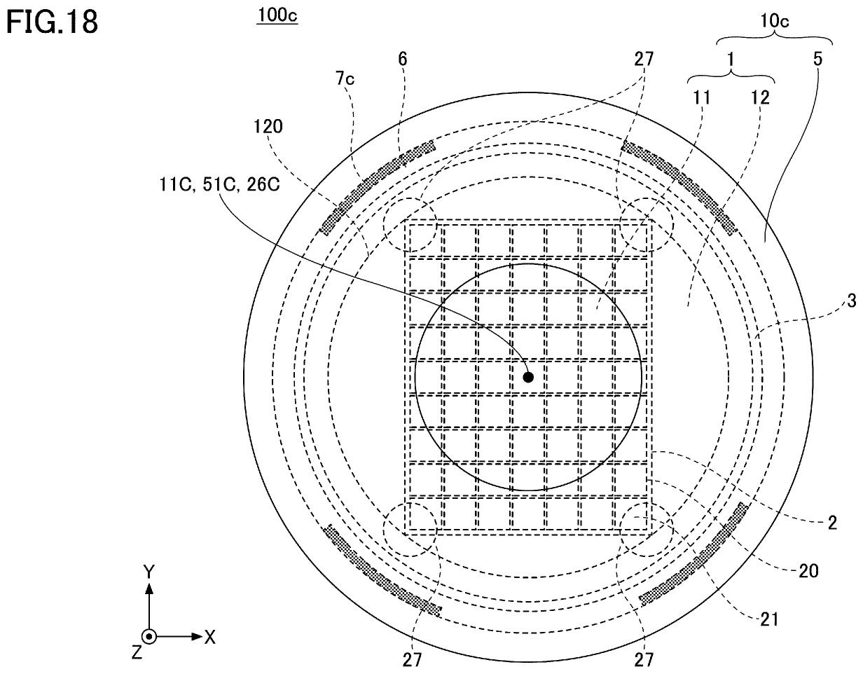

A configuration of a light-emitting module including a lens structure according to a modification of the third embodiment will be described with reference to FIG. 18. FIG. 18 is a schematic top view of a light-emitting module 100c including a lens structure 10c according to a modification of the third embodiment.

The light-emitting module 100c according to the present embodiment is different from the light-emitting module 100b according to the third embodiment in that a plurality of reflection portions 7c are disposed on the inner lateral surface 521 in the lens structure 10c.

In the present embodiment, the reflection portion 7c is not limited to a cylindrical shape along the cylindrical shape of the inner lateral surface 521, and may be locally disposed in portion(s) of the inner lateral surface 521 where there is a large amount of stray light. For example, the light source 2 may have a rectangular shape in a top view, and the reflection portion(s) 7c may be disposed so as to face the corner portion(s) 27 of the light source 2. In the example illustrated in FIG. 18, four reflection portions 7c are provided on the inner lateral surface 521 of the lens structure 10c so as to respectively face the four corner portions 27 of the light source 2. Because the corner portions 27 of the light source 2 are located at a long distance from the optical axis 11C, the light amount of the light L2 to be stray light tends to be large. A large amount of stray light is incident on portions of the inner lateral surface 521 facing the corner portions 27 of the light source 2. Because the reflection portion(s) 7c are locally disposed in the portion(s) of the inner lateral surface 521 where the amount of stray light is large, the amount of stray light is reduced while the amount of material constituting the reflection portion 7c is reduced, so that a large amount of irradiation light from the light-emitting module 100c is achieved.

While embodiments have been described in detail above, the present invention is not limited to the above-described embodiments. Various modifications and substitutions can be made to the above-described embodiments without departing from the scope described in the claims.

The ordinal numbers, quantity, and the like used in the description of the embodiments are all exemplified to specifically describe the technique of the present disclosure, and the present disclosure is not limited to the numbers exemplified. In addition, the connection relationship between the components is exemplified to specifically describe the techniques of the present disclosure, and the connection relationship for implementing the function of the present disclosure is not limited thereto.

The lens, the lens structure, and the light-emitting module of the present disclosure can reduce stray light, and thus can be suitably used for illumination, the flash of a camera, headlights on a vehicle, and the like. However, the lens, the lens structure, and the light-emitting module of the present disclosure are not limited to these uses.

What is claimed is:

1. A lens comprising:
a first lens portion having a positive refractive power; and
a second lens portion having a positive refractive power and located outward of an outer edge of the first lens portion in a top view; wherein:
the first lens portion has an optical axis, a first light incident surface, and a first light exit surface located opposite to the first light incident surface;
the second lens portion has a second light incident surface and a second light exit surface located opposite to the second light incident surface; and
in a cross section including the optical axis of the first lens portion:
the second lens portion has a lens main axis, and
the lens main axis of the second lens portion is inclined with respect to the optical axis of the first lens portion such that the lens main axis has an increasing distance from the optical axis toward the second light exit surface from the second light incident surface.

2. The lens according to claim 1, wherein an inclination of the lens main axis of the second lens portion with respect to the optical axis is in a range from 30 degrees to 50 degrees.

3. The lens according to claim 1, wherein the second lens portion has an annular shape in a top view.

4. The lens according to claim 1, wherein a thickness of a boundary between the first lens portion and the second lens portion is less than a maximum thickness of the second lens portion.

5. A lens structure comprising:
the lens according to claim 1; and
a light-transmissive member comprising:
a third lens portion disposed above the first lens portion and the second lens portion, and
a support portion supporting the third lens portion.

6. The lens structure according to claim 5, wherein:
the support portion has an inner lateral surface facing the second light exit surface; and
a reflection portion is disposed on the inner lateral surface of the support portion.

7. A light-emitting module comprising:
the lens according to claim 1; and
a light source facing a first surface of the lens, the first surface comprising the first light incident surface and the second light incident surface.

8. The light-emitting module according to claim 7, wherein at least a portion of the light source overlaps the second lens portion in a top view.

9. The light-emitting module according to claim 7, wherein the light source comprises a plurality of light-emitting units.

10. The light-emitting module according to claim 7 further comprising:
a light-transmissive member comprising:
a third lens portion disposed above the first lens portion and the second lens portion, and
a support portion supporting the third lens portion; wherein:
the lens has the first surface and a second surface located opposite to the first surface;
the second surface of the lens has the first light exit surface and the second light exit surface; and
the third lens portion of the light-transmissive member faces the second surface.

11. The light-emitting module according to claim 10, wherein:
the support portion has an inner lateral surface facing the second light exit surface of the second lens portion;
a reflection portion is disposed on the inner lateral surface of the support portion; and
the second lens portion is disposed inward of the reflection portion in a top view.

12. The light-emitting module according to claim 11, wherein:
the light source has a rectangular shape in a top view; and
the reflection portion faces a corner portion of the light source.

13. A light-emitting module comprising:
a lens comprising:
a first lens portion having a positive refractive power, and
a second lens portion having a positive refractive power and located outward of an outer edge of the first lens portion in a top view; and
a light source; wherein:
the first lens portion has an optical axis, a first light incident surface, and a first light exit surface located opposite to the first light incident surface;
the second lens portion has a second light incident surface and a second light exit surface located opposite to the second light incident surface;
the light source is disposed facing a first surface of the lens, the first surface comprising the first light incident surface and the second light incident surface;
the second lens portion is disposed in contact with an outer edge of the first lens portion; and
in a cross section including the optical axis, a boundary light beam emitted from a light-emitting point of the light source located immediately below a boundary between the first lens portion and the second lens portion, in a direction along the optical axis, exits the second light exit surface at an angle in a range from 30 degrees to 50 degrees with respect to the optical axis of the first lens portion such that the boundary light beam has an increasing distance from the optical axis, and passes through a peak point where illuminance of irradiation light from the light-emitting point is maximized on an irradiation plane that is orthogonal to the optical axis and located above the lens.

14. The light-emitting module according to claim 13 further comprising:
a light-transmissive member comprising:
a third lens portion disposed above the first lens portion and the second lens portion, and
a support portion supporting the third lens portion; wherein:
the lens has the first surface and a second surface located opposite to the first surface;
the second surface comprises the first light exit surface and the second light exit surface; and
the third lens portion of the light-transmissive member faces the second surface.

15. The light-emitting module according to claim 14, wherein:
the support portion has an inner lateral surface facing the second light exit surface of the second lens portion; and
a reflection portion is disposed on the inner lateral surface of the support portion.

16. The light-emitting module according to claim 15, wherein:
the light source has a rectangular shape in a top view; and
the reflection portion faces a corner portion of the light source.

17. The light-emitting module according to claim 15, wherein a traveling direction of light reflected by the reflection portion after passing through the second lens portion, in the boundary light beam, is along a traveling direction of light passing through the first lens portion, in the boundary light beam.
